(19) United States
(12) Patent Application Publication
(10) Pub. No.: US 2004/0112633 A1
(43) Pub. Date: Jun. 17, 2004

(54) Electronic device module

(76) Inventors: Mitsuyoshi Endo, Kanagawa (JP); Toshiro Hiraoka, Kanagawa (JP); Yasuyuki Hotta, Tokyo (JP); Hideo Aoki, Kanagawa (JP); Hideko Mukaida, Tokyo (JP); Naoko Yamaguchi, Kanagawa (JP)

Correspondence Address: Finnegan, Henderson, Farabow,, Garrett & Dunner, L.L.P., 1300 I Street, N.W., Washington, DC, 20005-3315, US

(21) Appl. No.: 10/654,920

(22) Filed: Sep. 5, 2003

(30) Foreign Application Priority Data
Sep. 5, 2002 (JP) 2002-260514

(51) Int. Cl. H05K 1/03; H05K 7/06

(52) U.S. Cl. 174/255; 174/258; 174/260

(57) ABSTRACT

An electronic device module comprises a wiring substrate having an insulating substrate with a porous structure including continuous pores and wiring conductors selectively formed in the porous structure; and an electronic device directly connected to said wiring conductors formed in the porous structure. A manufacturing method of an electronic device module comprises mounting an electronic device on a surface of an insulating substrate having a porous structure including continuous pores and including photosensitive material which produces or vanishes ion exchange groups upon exposure to energy rays using a mask; exposing the energy rays to change the photosensitive material; and

performing electroless plating to form wiring conductors in continuous pores generated by the change of the photosensitive material.

### CROSS REFERENCE TO RELATED APPLICATION

This application is based upon and claims the benefit of priority from the prior Japanese Patent Application No. 2002-260514, filed on Sep. 5, 2002; the entire contents of which are incorporated herein by reference.

### BACKGROUND OF THE INVENTION

The present invention relates to an electronic device module having electronic devices such as a semiconductor chip and wiring substrates integrated therein.

To attain enhanced performance of mobile information/communication tools, smaller-sized, lighter-weighted and slimmer packages and modules are required for hyper large scale integration with electronic devices. In manufacturing a semiconductor package where it is desired to accommodate a semiconductor chip with terminals provided at reduced pitch, for instance, various connection techniques such as tape automated bonding (TAB), flip chip bonding, and the like have been introduced in practice.

A structure of a package fabricated by the prior art flip chip bonding is illustrated in FIG. 1. For both or one of a semiconductor chip 1 and a wiring substrate 2, terminal electrodes 12 are prepared by forming bumps 4 of gold or solder material in advance. The semiconductor chip 1, having its terminal pads at the bottom, is aligned in position onto the wiring substrate 2, and then subjected to heating and pressing treatments for connecting terminals and securing the chip. Clearances between the chip 1 and the wiring substrate 2 are sealed with resin 3, as required.

A method of fabricating multi-layered wiring substrate has already been proposed by the inventors of this application where a porous sheet is impregnate with conductive material that is introduced in predetermined patterns for via holes (through-holes) and wirings (interconnections) (see Japanese Unexamined Patent Publication No. 2001-83347). An improved porous sheet of plain weave fabric is also disclosed (see Japanese Unexamined Patent Publication No. H10-321989).

Since a coefficient of thermal expansion of the semiconductor chip considerably varies from that of the wiring substrate, a greater stress is applied to junctions between the semiconductor chip and the wiring substrate during the prior art flip chip bonding process, which may cause a trouble that the contact bumps on the semiconductor chip are separated and disconnected from the wiring substrate.

Also, in the conventional flip chip method, since the contact bumps have nearly the same height with the thickness of the semiconductor chips or of the wiring substrates are required, the semiconductor chip cannot be closely contact to the wiring substrate, which is an obstacle to thinning or slimming the package. Another obstacle to the thinning is a necessity of formation of stress relaxation layer between the semiconductor chip and the wiring substrate to prevent separation of the semiconductor chip from the wiring substrate. Thus, the slimming of the package is difficult unless some revised method is used other than the prior art flip chip bonding in addition to the fact that this prior art bonding method is prone to cause a disconnection of the junction between the semiconductor chip and the wiring substrate.

Thus, the package fabricated by the prior art flip chip bonding process has a difficulty in thinning the package. Furthermore, the package fabricated by the prior art flip chip bonding process also leads to a high process cost because of an unavoidable necessity of the formation of the contact bumps on the semiconductor chip and the wiring substrate and the heating and pressing treatments. Still further, if a reduction of the terminal pitch for the semiconductor chip, for example, down to 50 μm or less, a difficulty in alignment of the semiconductor chip with the package and also in a flip chip process will increase because limitations on manufacturing and alignment tolerances of the production machine may exceed their allowable ranges.

### SUMMARY OF THE INVENTION

According to an embodiment of the present invention, there is provided an electronic device module comprising:

a wiring substrate having an insulating substrate with a porous structure including continuous pores and wiring conductors selectively formed in the porous structure; and

an electronic device directly connected to said wiring conductors formed in the porous structure.

According to another embodiment of the present invention, there is provided a manufacturing method of an electronic device module comprising:

mounting an electronic device on a surface of an insulating substrate having a porous structure including continuous pores and including photosensitive material which produces or vanishes ion exchange groups upon exposure to energy rays using a mask;

exposing the energy rays to change the photosensitive material; and

performing electroless plating to form wiring conductors in continuous pores generated by the change of the photosensitive material.

### BRIEF DESCRIPTION OF THE DRAWINGS

FIG. 1 is a sectional view showing a structure of a prior art flip chip mounted package;

FIG. 2 is a sectional view showing a structure of an exemplary semiconductor chip package according to an embodiment of the present invention;

FIGS. 3A to 3C are sectional views illustrating steps of manufacturing the exemplary chip package;

FIG. 4A is a plan view showing a wiring of a wiring substrate in the exemplary semiconductor chip package;

FIG. 4B is a sectional view taken along the line I-I′ of FIG. 4A;

FIG. 4C is a diagram illustrating an effect of leakage light occurring in FIG. 4B;

FIG. 5 is a plan view showing a semiconductor chip built in the exemplary package;

FIG. 6 is a sectional view showing a structure of another embodiment of the semiconductor chip package;

FIG. 7 is a sectional view showing a structure of still another embodiment of the semiconductor chip package;

FIG. 8 is a sectional view showing a structure of further another embodiment of the semiconductor chip package;

FIG. 9 is a sectional view showing a structure of another embodiment of the semiconductor chip package;

FIG. 10 is a sectional view showing a structure of yet another embodiment of the semiconductor chip package;

FIGS. 11A to 11D are sectional views showing exemplary steps of manufacturing the semiconductor ship package;

FIGS. 12A to 12C are sectional views showing a structure of another embodiment of the package;

FIGS. 13A to 13C are sectional views showing a structure of further another embodiment of the package;

FIGS. 14A and 14B are sectional views showing a structure of another embodiment of the package; and

FIGS. 15A to 15D are sectional views showing a structure of further another embodiment of the package.

### DETAILED DESCRIPTION

Embodiments of the present invention will now be described in conjunction with the accompanying drawings. In the following discussion, a semiconductor package will be exemplified as an electronic device module.

FIG. 2 shows a cross sectional structure of such an exemplary semiconductor package in accordance with an embodiment of the present invention. A semiconductor chip 11 has its terminal electrodes 12 directly connected with wiring conductors 22 in a wiring substrate 20 without intervening bumps.

The wiring substrate 20 is made of porous insulation substrate 21 of which porous structure having continuous pores is used to thread the wiring conductors 22 therethrough. The wiring conductors 22 are grouped into conductors 22a and 22b, and the former is of wirings provided on the bottom surface which is in parallel with the principal surface of the substrate while the latter is of wirings passing through the substrate from its top to bottom. To form the conductors 22a and 22b, the semiconductor chip 11 undergoes pattern exposure and electroless plating while kept in contact with the insulating substrate 21. The conductor 22b includes a metal deposition layer growing from the surfaces of the terminal electrodes 12 of the semiconductor chip 11, and thus, part of the conductor 22b in contact with the terminal electrodes 12 becomes a bonding layer to give electrical and mechanical contact of the wiring substrate 20 with the semiconductor chip 11. The porous insulation substrate 21 is preferably impregnated with resin, e.g. thermosetting resin that is cured in its porous structure to enhance mechanical strength and reliability of the wiring substrate 20 and additionally to bond the wiring substrate 20 to the semiconductor chip 11 into a unit.

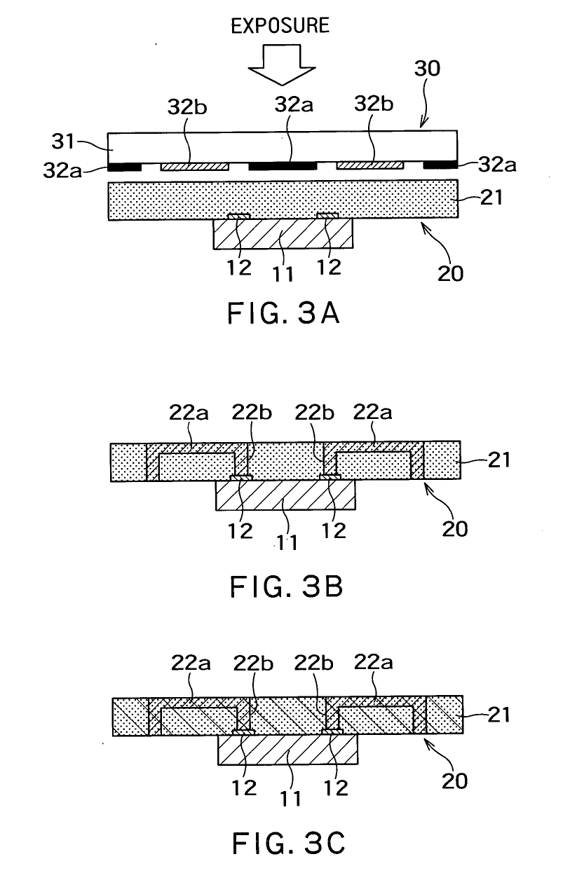

FIGS. 3A to 3C are sectional views illustrating steps of manufacturing the above-mentioned embodiment of the semiconductor package. As can be seen in FIG. 3A, the semiconductor chip 11 has its surface with the terminal electrodes 12 joined onto the porous insulation substrate 21, which is to work as the wiring substrate 20. The insulation substrate 21 includes a photosensitive layer that is, upon exposure to irradiated energy rays, capable of producing or dissipating ion exchange group. For temporary bonding of the chip 11 to the insulation substrate 21, the insulation substrate 21 may be provided with an adhesive layer in advance, or otherwise, the insulation substrate 21 itself may be of adhesive substrate material.

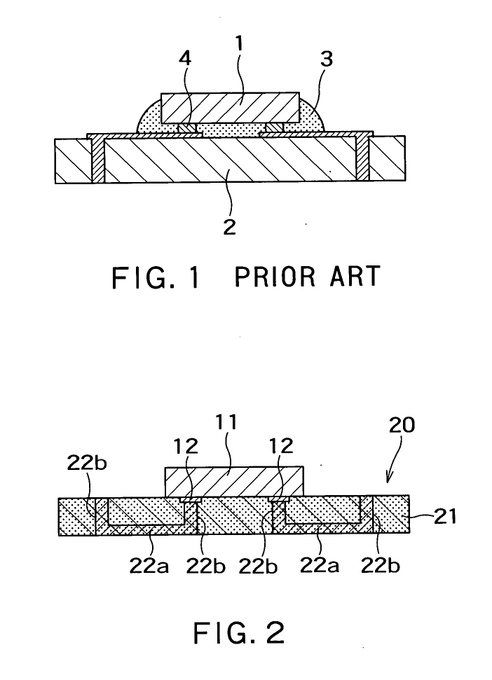

Then, a photomask is set on a side of the insulation substrate 21, which is the opposite surface to the semiconductor chip 11 provided, and these are exposed to light to define conductive wirings in a predetermined pattern. As the photosensitive layer included in the insulation substrate 21, exposed to light, produces ion exchange group, the photo-mask 30 is made of a glass substrate 31 on which two types of mask materials 32a and 32b are provided in predetermined patterns to let light transmit only to totally or partially unmasked pre-wiring regions. One of the mask materials, namely, mask 32a is for completely shielding substrate areas that are to be left without conductive wirings. The other mask 32b works as a partial shield mask having light transmittance of tens percent that occupies the pre-wiring areas for only the conductor 22a extending in parallel with the substrate 21 as in FIG. 1. The remaining light transmitting areas without the mask materials are defined for the conductor 22b extending through the substrate 21 also as shown in FIG. 2.

When an exposure is performed using such a photo-mask 30, dimensions and depth the transmitted light reaches vary from part to part in the exposed substrate, depending upon the mask patterns, and thus, a depth of areas where ion exchange group are to be produced can be under control. Specifically, the partial shielding mask 32b permits the ion exchange group to be produced only in the surface of the substrate 21, and the areas without the mask materials do to the full depth through the substrate 21 by virtue of a sufficient amount of light. A distribution of the ion exchange group is reflected to a latent image of the wiring conductors.

After that, the insulation substrate 21 undergoes electroless plating, and resultantly, the ion exchange group in the porous structure attract metal ions or metal colloid. As shown in FIG. 3B, this enables the wiring conductors 22 to be defined at varied depths, depending upon the predetermined exposure pattern and the strength of the transmitted light. In this way, the wiring conductors 22 include the conductor 22a extending around the surface exposed to light and in parallel with the substrate 21 and the conductor 22b (through conductor) extending from the conductor 22a through the substrate 21 to the opposite side thereof.

During the plating, the surface of the semiconductor chip 11 is coated with an appropriate protection film so as not to deposit metal. The conductor 22b formed during the plating also serves as the bonding layer to the terminal electrodes 12 of the semiconductor chip 11 to make mechanical and electrical contacts directly with the terminal electrodes 12. After that, as required, as shown in FIG. 2C, the insulating substrate 21 is impregnated with resin.

More detailed explanations will be given below. The porous insulating substrate 21 should have continuous hollow pores therein and may be made of organic or inorganic material. The organic materials for the insulating substrate include resins such as epoxy, bismaleimide-triazine, poly etheretherketone (PEEK), and butadiene that are all well-known in the art as suitable for printed wiring boards. Any of these polymer materials can be processed into porous substrate (sheet) by means of a suitable method such as orientation, phase conversion, or the like.

The inorganic insulating substrate may be made of ceramics which include metal oxide such as silica, alumina, titania, titanic potassium, and the like, and other materials such as silicon carbide, silicon nitride, aluminum nitride, and the like. Any of these ceramics may be processed into the porous substrate by means of sol-gel process, emulsion templating, or the like.

Alternative to the above for the insulating substrate 21 is composite materials of inorganic material with organic material; for example, polymer such as polyimide and polyamide with dispersing ceramics filler such as silica and alumina therein is suitable.

The porous structure of the insulating substrate is preferably the one configured in three-dimensional network where continuous hollow pores uniformly extend from openings conducting to the outside of the substrate and divide throughout the substrate. Because of such a three-dimensional network porous structure, the impregnant conductive material, filling the pores in the insulating substrate continuously in the three-dimensional manner, can be retained well and fixed stably. Since the hollow pores filled with the conductive material continuously spreads in a depthwise direction as well as in a horizontal direction, both the feedthrough and non-feedthrough conductors can be defined, and additionally, a satisfactory conductivity can be attained.

A porous sheet of honeycomb structure and a mesh sheet of plain weave fiber, which do not have three-dimensional continuous hollow pores, supposedly cannot attain the similar effects. For example, the mesh sheet of plain weave fiber, which is disclosed in Japanese Unexamined Patent Publication No. H10-321989), may afford some horizontal penetration of the conductor material, but most of the horizontal conductor must be provided above and below the sheet to keep sufficient conductivity. As a consequence, conductor patterns and the remaining non-conductor areas interlace in an intermittent uneven structure, which causes a difficulty in creating a lamination, and if laminated, multi layers could not permit the interlayer insulation film to be uniform in thickness, which also results in an unsatisfactory property of radio frequency. When the through-holes and wirings are miniaturized, the dimensions of the conductor patterns and a thickness of fibers become close to each other, and this causes an additional difficulty in creating the through-holes of reduced diameter. Moreover, a width of the wirings is not constant, which would be an additional cause of a significant degradation of the radio frequency property. With non-woven fabric which is generally of fibers dimensioned as much as 10 μm or even greater, the similar problems as in the porous sheet of honeycomb structure and the mesh sheet might be caused. Especially, it should be so hard to build a multi-dimensional miniature wiring structure of the through-holes and wirings. A solution to these problems will be the porous insulation substrate with three-dimensional continuous hollow pores of which diameter is sufficiently smaller than the dimensions of the conductor patterns, or preferably, one tenth of the dimensions or even smaller.

It is preferable that the hollow pores occupy 40% to 95% of the whole porous structure in the insulating substrate, and more preferably, 50% to 85%. When this percentage is excessive, mechanical strength and dimensional stability of the insulating substrate are perceived insufficient. Reversely, too small the percentage may disturb a penetration of the conductor material, which leads to a difficulty in attaining a sufficient conductivity. The percentage of the hollow pores can be observed by a device such as an electron microscope. It can be calculated by obtaining a specific gravity of the insulating substrate.

An average diameter of the hollow pores in the porous structure of the insulating substrate is preferably 0.05 to 5 μm. An excessive diameter of the hollow pores causes a difficulty in miniaturizing the conductors. Especially, when the conductors are defined by means of exposure as mentioned above, light scattering is too excessive to perform an appropriate exposure for miniaturized patterns. On the contrary, an excessively small diameter of the hollow pores disturbs the penetration of the conductor material. Besides the pore diameter, pore pitch is also an important factor. In a region where the pitch is greater or where no pore exists, light scattering is excessive, which means a loss of control over light to which the insulating substrate must be exposed sufficiently deep in the desired patterns.

A radius of gyration of the region without pore is preferably 10 μm or smaller, more preferably, 5 μm or smaller. It is also preferable that the regions without pores is not localized but dispersed uniformly. An average diameter of the hollow pores and the radium of gyration of the regions without pores can be determined by means of light scattering method and X-ray scattering method.

A sheet thickness of the insulating substrate should preferably be 10 times or more than the average pore diameter, more preferably, 50 times or more. When the sheet thickness is excessively small relative to the pore diameter, the resultant conductors are prone to be undesirably shaped in their depthwise direction, which results in a degradation of an electrical property of the conductors. The conductors are built up by an aggregation of the conductor material filling the hollow pores. Excessively large pore diameter relative to the sheet thickness causes a difficulty in shaping the conductor in the depthwise direction to attain a satisfactory resolution. Especially, in defining both the feedthrough and non-feedthrough conductors in the single sheet, the diameter of the hollow pores must be sufficiently small relative to the sheet thickness. When the pore diameter is excessively large relative to the sheet thickness, the sheet lacks a sufficient expandability in the depthwise direction, which results in an insufficient capability of backing the uneven surface of the electronic device.

A preferable sheet thickness of the porous insulating substrate is appropriately determined by the aforementioned relations of the diameter of the hollow pores and the number of the wiring layers included in the single sheet. When the feedthrough conductor in the depthwise direction is defined in the single sheet, it is preferable that the thickness of the sheet is 5 to 30 μm. Excessively thinning the sheet leads to a difficulty in handling it, and disturbs ensuring a sufficient insulation between the wiring layers. Reversely, the excessively thick sheet causes a difficulty in getting the conductor from side to side in the depthwise direction. Also, when it is desired that the wiring layer and the through-holes connecting it to the electrodes are included in the single sheet, the thickness of the insulating substrate is preferably 10 to 200 μm, more preferably, 40 to 100 μm.

The insulating substrate 21 is preferably made of a material of a coefficient of thermal expansion almost as low as that of the semiconductor chip 11. This can prevent thermal stress from acting upon the junction of the semiconductor chip 11 with the wiring substrate 20 to separate the former off the latter and/or to cause cracks in the wiring substrate and chip.

The wiring conductors 22 would not be separated off the substrate because it is defined in the porous structure of the insulating substrate 21.

The photosensitive layer formed in the insulating substrate 21 may have photosensitive group capable of producing or dissipating ion exchange group upon exposure to energy rays.

Particles that produce the ion exchange group upon exposure to energy rays include such as o-nitorobenzyl ester derivatives of carboxylic acid, sulfonic acid, or silanol, and p-nitorobenzyl ester derivatives of carboxylic acid, sulfonic acid, or silanol.

The photosensitive group dissipating the ion exchange group upon exposure to the energy rays contain the ion exchange group in some part before the exposure, and such the ion exchange group are eliminated due to the exposure to energy rays. Otherwise, the photosensitive group may have an attribute transformable into hydrophobic group, and an example is carboxyl derivative group decomposable due to decarobxylation reaction. The photosensitive layer defined in the insulating substrate 21 is preferably made of polymer material initially having the photosensitive group, or alternatively, it may be formed by a series of treatments of impregnation with solution of photosensitive material and subsequent drying.

To form the wiring conductors in corresponding shape to the latent image of the ion exchange group produced by exposure of the insulating substrate 21 to light, metal ions are first attracted to the pattern of the ion exchange group, and then are reduced to metal particles as required, and after that, the insulating substrate is subjected to a treatment of electroless plating. When plating solution exuding from the insulating substrate 21 is left in contact with the terminal electrodes 12 on the semiconductor chip 11, metal is grown from the surfaces of the terminal electrodes of copper, gold, silver, palladium, nickel or the like. The grown metal, merged with metal deposited in the insulating substrate 21, provides satisfactory mechanical and electrical contacts of the conductor 22 or the via wirings with the terminal electrodes 12. Especially, when the semiconductor chip 11 and the terminal electrodes 12 are of the same metal such as copper, insertion of heterogeneous metal into the junction or the interface therebetween is needless to reinforce the contacts.

In this embodiment, unlike the flip chip bonding, the semiconductor chip can be mounted on the wring substrate without forming bumps. Thus, the thinning or slimming of the package can be attained. Also, the matching of the semiconductor chip to the wiring substrate can be performed without alignment as required in the flip chip bonding, but rather, the status of the contacts of the wiring conductors in the wiring substrate with the terminal electrodes in the semiconductor chip depends upon the process of exposure of the wiring substrate overlaid with the chip. Thus, the semiconductor chip having the terminal electrodes at a minute pitch does not have to be assembled by strict alignment as required in the prior art.

In this embodiment, also, as mentioned above, the wiring conductors 22 are made all at once; i.e., both the conductor 22a in parallel with the wiring substrate 20 and the conductor 22b (feedthrough conductor) extending from the conductor 22a through the substrate 20 to the opposite sides thereof can be formed altogether. In this way, in principle, the conductors 22a and 22b would not be in misalignment, and therefore, it is needless to provide a land occupying a greater area than the wirings as required in an ordinary interlaminator bonding for the margin prepared for the misalignment.

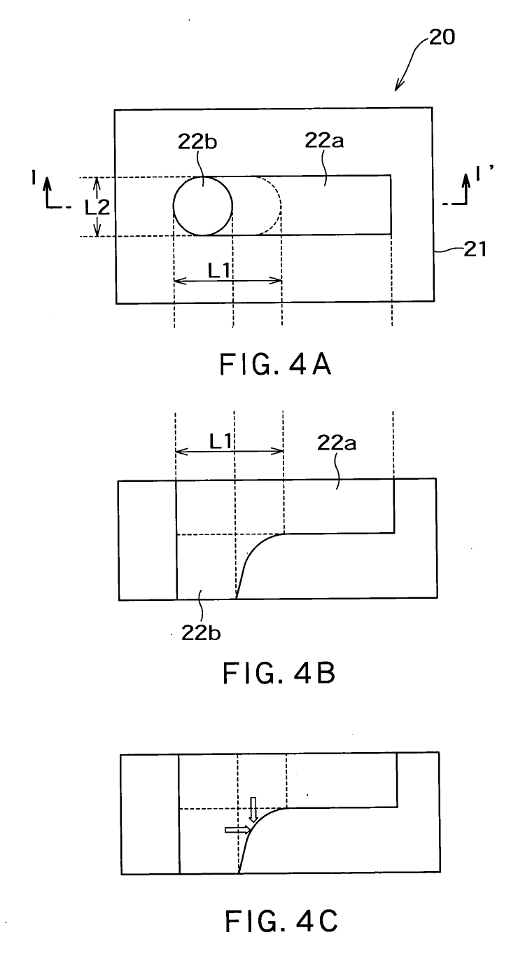

For more details of this embodiment, FIGS. 4A and 4B are a plan view of the wiring conductors 22 in the wiring substrate 20 and a sectional view taken along the line I-I′. The conductor 22a serving as the transverse wirings is constant in width (a dimension of its narrower extension) till it reaches the conductor 22 serving as the via wirings, and the land is needless for the conductor 22b. In the boarder of the light transmitted areas and the partial shield area in the photo-mask 30, the strength of irradiated light transits gradually as it goes deeper in the substrate, and hence, the conductor 22b during the practical plating procedure varies its width only in the transverse direction without exceeding the thickness of the substrate, as shown in FIG. 4B.

In the intersection of the conductors 22a and 22b, the conductor 22b along the longer extension of the conductor 22a is wider than itself along the shorter extension of the conductor 22a. This is because, as will be recognized in FIG. 4C, leakage fractions from the exposing light for the conductors 22a and 22b, respectively, act cooperatively, and the resultant conductor 22b spreads only along the longer extension of the conductor 22a. The leakage light is denoted by arrows in FIG. 4C. Thus, without needlessly forming the land, the conductors 22a and 22b can meet each other at a sufficient intersecting area contoured by smooth curves. In this manner, the junction of the conductors 22a and 22b, having no inadequate break, is highly reliable and attains a satisfactory electrical property.

The conductors 22b and 22a are preferably shaped so that, in the junction of them, one diameter L1 of the conductor 22b along the longer extension of the conductor 22a is longer than another L2 along the shorter extension of the conductor 22a. A rate of the L1 to L2 (L1/L2) is preferably 1.2 or higher, and more preferably, 1.5 or higher. When the value L1/L2 is smaller than that level, the aforementioned reliability and electrical property will be unsatisfactory. There is no limit to the upper extreme of L1/L2, but preferably, the rate should be 3.5 or below, more preferably, 2.5 or below. Excessively great value of L1/L2 will cause a difficulty in impedance matching.

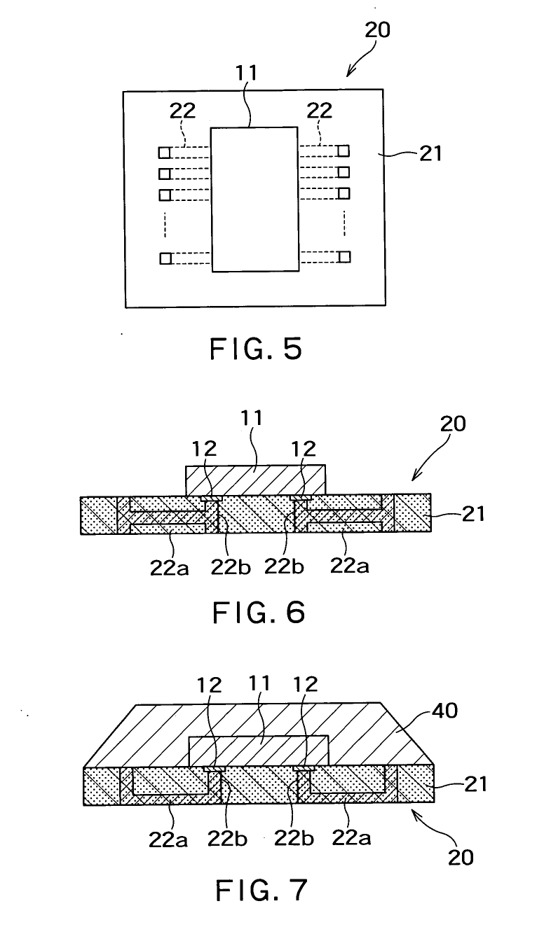

FIG. 5 is a plan view of this embodiment showing the semiconductor chip 11 provided with a plurality of terminal electrodes at a minute pitch and mounted onto the wiring substrate 20. As mentioned above, the wiring conductors 22 are formed at the same intervals without the land, and this facilitates the formation thereof at a minute pitch identical with the terminal pitch of the semiconductor chip, which enables downsizing of the package.

Moreover, the wiring substrate 20 may be made of material of a coefficient of thermal expansion as low as that of the semiconductor chip 11 to prevent the chip from separation due to thermal stress, and thus, he reliable package can be obtained. The wiring conductors are formed in the insulating substrate, and this improves a tight bonding of the wiring conductors to the substrate and prevents the wirings from peeling off.

FIG. 6 depicts a structure of another embodiment of the package in contrast with the embodiment in FIG. 1. This embodiment is different from that in FIG. 1 in that only the conductor 22a extending in parallel with the major surface of the substrate is embedded in the midst of the substrate 21. Such a structure can be obtained by the same manufacturing steps as discussed in FIG. 1 but the step of exposure.

During the procedure of exposure, while exposing the substrate with the partial shield mask 32b as used in the aforementioned embodiment, light is converged by a lens and directed at the midst of the insulating substrate 21. This enables the formation of the conductor 22a embedded in the insulating substrate 21.

FIG. 7 shows a variation of the package shown in FIG. 2 where the semiconductor chip 11 is covered with mold resin 40. This embodiments improves the anti-humidity and anti-shock characteristics.

The embodiments which have been previously discussed commonly include the wiring substrate 20 that functions to be the package base. Thus, in practical use, bumps will be provided at wiring ends of the feedthrough conductor 22b exposed from the wiring substrate 20 on the opposite side from the semiconductor chip 11, so that the bumps serve as contacts of the package to wirings of other modules such as a printed circuit board.

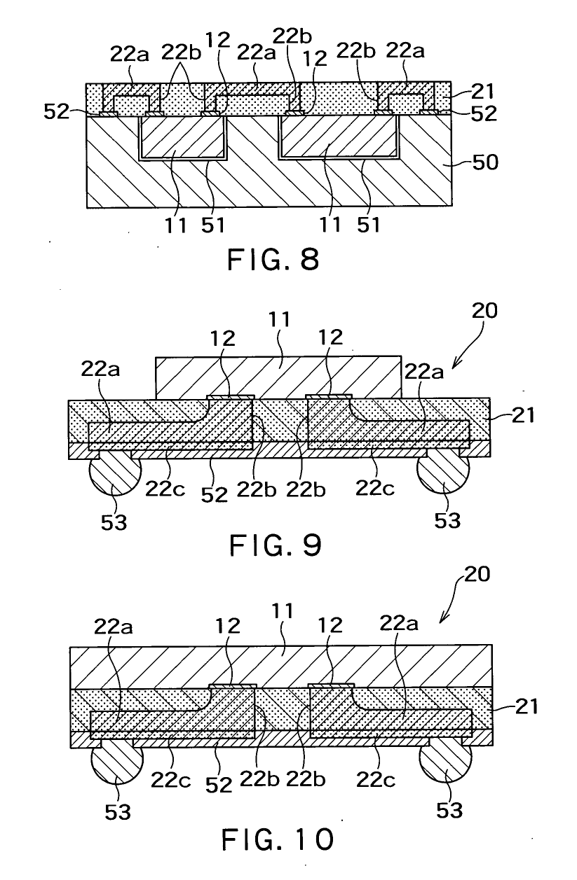

FIG. 8 depicts a structure of another embodiment of a module. Two of the semiconductor chips 11 are shown in the drawing, being mounted on a package base 50 prepared in addition to the wiring substrate 20. Specifically, the package base 50 has recesses 51, and the semiconductor chips 11 are mounted on the base 50, being cupped in the recesses 51.

Similar to the previous embodiments, the package substrate 50 is overlaid with the porous insulating substrate 21 to embed the semiconductor chip 11, and the terminal electrodes 12 of the semiconductor chip 11 are in contact with the terminal electrodes 12 on top of the semiconductor chips 11. The lamination of the substrates and chips is subjected to a series of treatments of pattern exposure and electroless plating. In this way, the conductor 22a providing transverse wirings and the conductor 22b extending through the insulating substrate 21 are defined.

Although the embodiments where the electronic device is exemplified simply as the semiconductor chip have been discussed, the present invention should not be limited to this, but it is also effective in variations where a variety of electronic devices such as a capacitor, a resistance, a coil, and other chip devices are packaged together or assembled in a module.

An exemplified structure of the aforementioned electronic module will be detailed below. FIG. 9 is a sectional view showing an example of a semiconductor package according to the present invention. The semiconductor chip 11 and the porous insulating substrate 21 are tightly bonded together, and the insulating substrate is provided with the conductor 22b (via wirings, vias) connected to the terminal electrodes 12 of the semiconductor chip 11 and the conductor 22a (wirings). The conductor 22a has external protrusions 22c partially raised from the insulating substrate 21, which is useful to reduce resistance of the wirings. The semiconductor chip 11 and the insulating substrate 21 are bonded together by curable resin impregnating the insulating substrate 21. Part of the resin penetrating the insulating substrate 21 creates an overlying solder-resist layer 52. The conductors 22a and 22c are connected to bumps 53 provided over the solder-resist layer 52.

The semiconductor package fabricated in this manner has the conductors 22b (vias), 22a, and 22c (wirings) are integrated in the insulating substrate 21, and such an integrated configuration is effective to avoid damage caused by stress due to the difference of a coefficient of thermal expansion between the semiconductor chip 11 and the insulating substrate 21. Especially, the interface between the conductor 22b (vias) and the terminal electrodes 12 as well as the interface between the conductors 22b and 22c (wirings) can be sealed tightly. Since the solder-resist layer 52 and the resin penetrating in the insulating substrate 21 are cured into a unit, the solder-resist layer 52 hardly be separated from the insulating substrate 21 at their interface, and the device reliability is enhanced. In FIG. 9, the insulating substrate 21 is dimensioned greater than the semiconductor chip 11, but alternatively, as shown in FIG. 10, the package may include the semiconductor chip 11 and insulating substrate 21 of the same chip size.

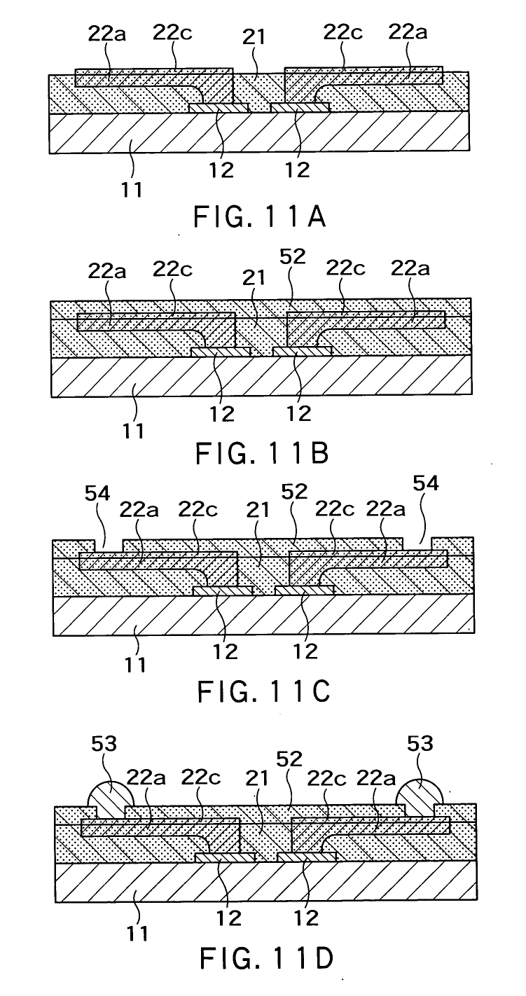

Manufacturing steps for the semiconductor packages in FIGS. 9 and 10 are shown in FIGS. 11A-11D. First, in the method as discussed above, fabricated in advance is the porous insulating substrate 21 that is bonded tightly to the semiconductor chip 11 and that has the conductor 22b (vias) in contact with the electrodes 12 and the conductor 22c (wirings) (see FIG. 11A).

Then, the insulating substrate 21 is impregnated with curable resin. Hardening the resin permits the semiconductor chip 11 to be bonded to the insulating substrate 21. During the impregnation, the resin is deposited over the insulating substrate 21 into a raised portion or the solder-resist layer 52 (see FIG. 11B). A predetermined region of the solder-resist layer 52 is eliminated by laser to define apertures for solder bumps (see FIG. 11C). After growing Ni—Au metal over the aperture, the solder bumps 53 are shaped to finish the semiconductor package (see FIG. 11D).

When semiconductor chips are employed in the fabricating process, separate chips already divided from a wafer as well as a wafer having a plurality of chips thereon can be used. In the latter case, the wafer provided with circuits is overlaid and bonded with the insulating substrate before the above-mentioned process. After processed, the wafer is divided into chip sized packages.

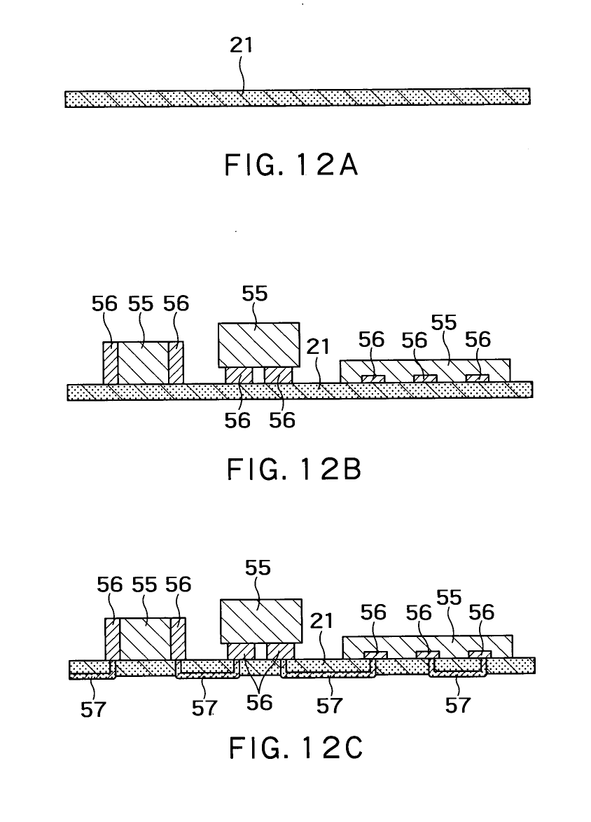

Next, shown in FIGS. 12A-12C is a module having a plurality of electronic devices connected together and a method of manufacturing the same. First, a plurality of the electronic devices 55 (see FIG. 12B) on the insulating substrate 21 as shown in FIG. 12A, then wirings 57 is formed in the insulating substrate, mutually connecting electrodes 56 of the electronic devices 55 to complete a module 57 (see FIG. 12C).

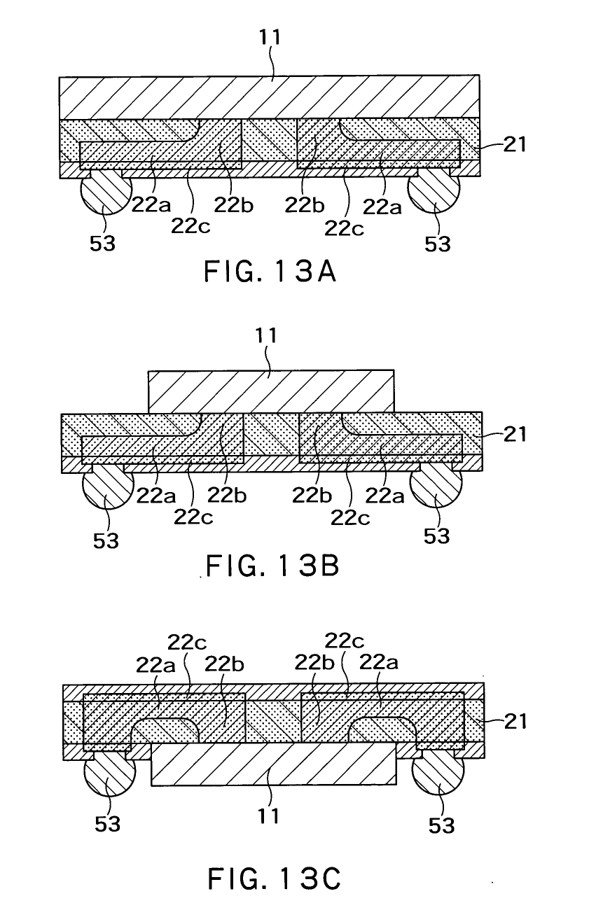

FIGS. 13A to 13C depict an exemplified semiconductor package structure. In these figures, electrodes 12 shown in FIGS. 9, 10, etc. are not provided. FIG. 13A corresponds to FIG. 10 and FIG. 13B corresponds to FIG. 9. FIGS. 13A and 13B show face-up type module where the semiconductor chip 11 is mounted on the top surface of the substrate, which is opposite side of the substrate on which bumps 53 are provided. FIG. 13C shows a face-down type module where the semiconductor chip 11 is mounted on the bottom surface of the substrate, which is the same side of the substrate on which bumps are provided.

In FIGS. 13A-13C, a single layer of horizontal wirings is illustrated, but two or more of the wiring layers may be provided. The bumps are solder bumps in this embodiment, but, as will be recognized, they may be replaced with other appropriate type of bumps.

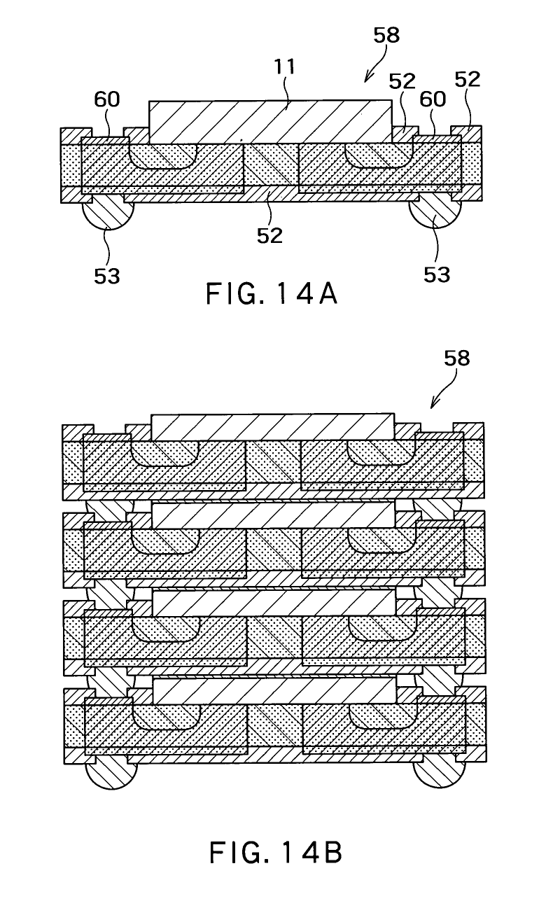

FIGS. 14A and 14B illustrates examples of a unit package 58 (see FIG. 14A) and a stacking 59 of those packages (see FIG. 14B). The unit package 58 has its bottom surface provided with the solder bumps 53 and its upper surface provided with mount pads 60 which are for contact with the solder bumps. The solder bumps of the package 58 are positioned on the mount pads 60 of the package to stack many of them up into the stacked package 59.

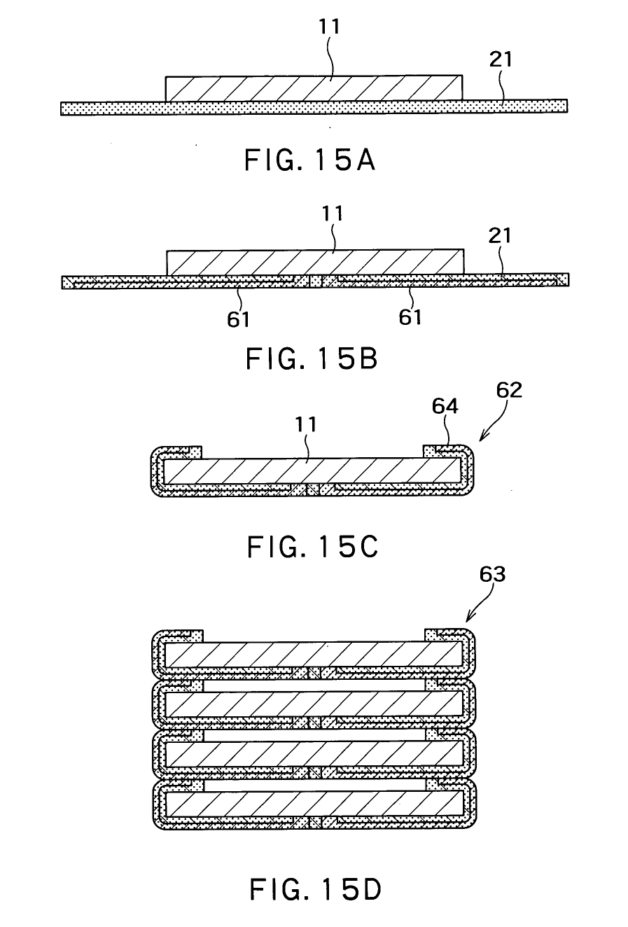

Another example of the stacked package may be the one as shown in FIG. 15. As shown in FIG. 15A, the porous insulating substrate 21 is bonded to the semiconductor chip 11. After that, as shown in FIG. 15B, conductor 61 is formed, being connected to the terminal electrodes (not shown) of the semiconductor chip, and subsequently, as shown in FIG. 15, the insulating substrate 21 is buckled or folded over the upper surface of the semiconductor chip to finish a unit package 62. After the insulating substrate 21 is impregnated with resin, many of the unit packages 62 are stacked up into a stacked package 62, as shown in FIG. 15D. Since the insulating substrate is of porous material, the impregnant resin, when cured, bonds the unit packages together in a unit to effectively avoid exfoliation of the unit packages, and the finished packages are very reliable. The insulating substrate 21, which is provided with a latent image of the conductors in advance, may be buckled and plated to define the conductor 64 in an initially crooked pattern. “Buckling and then plating” will cause much less damage on the conductor 61 during the buckling.

### PRACTICAL EXAMPLES

Practical examples of the present invention will be described in more detail below, but the invention should not be limited to the precise form in the descriptions.

For the electronic device, a semiconductor chip having a thickness of 50 μm, a pad diameter of 100 μm, and a pad pitch of 200 μm was used. The surfaces of pads were of copper activated by palladium immersion plating. The reverse and lateral sides of the semiconductor chip were hydrophobically modified by silane coupling agent.

A hydrophilically modified PTFE porous sheet (average diameter 0.1 μm of hollow pores, film thickness 60 μm) was prepared to provide package wirings therein, and the porous sheet had its one side coated with acrylic adhesive solution and then dried. The acrylic adhesive solution was a solution of copolymer of 2-ethyl hexylacrylate, methyl methacrylate, and acrylic acid mixed with isocyanate cross-linking agent and terpene tackifier resin. The PTFE porous sheet, after coated with the mixed solution and then dried, obtained adhesiveness as a result of the copolymer crosslinked by the isocyanate cross-linking agent. An organic photosensitive composition of naphthoquinone diazide containing phenolic resin (naphthoquinone diazide content 33 weight per equivalent (mol %)) was solved in acetone to make a preparation of acetone solution by 1 wt %. The porous sheet had its surfaces completely coated with the solution thus obtained by dip coating and was left at the room temperature for 30 minutes to dry. Then, inner surfaces of the pores of the substrate were covered with naphthoquinone diazide containing phenolic resin to obtain the photosensitive adhesive porous sheet.

The porous sheet was overlaid with the semiconductor chip having its pads located in the interface, and then treated under pressure of 10 g/cm² to bond them by the adhesive. After the bonding, the substrate is exposed using a stepper CANON™ PLA501 by employing a mask having line width 20 μm and space 30 μm at an exposure of 200 mJ/cm² (wavelength 436 nm) to develop an indene carboxylate latent image of a wiring pattern in the photosensitive layer. Furthermore, another exposure was performed using another mask having a pattern for via-holes of diameter 50 μm at light exposure of 2000 mJ/cm² (wavelength 436 nm) to develop a latent image of the via-hole patterns.

After the latent images of the wiring and via-hole patterns were developed, the insulating substrate along with the semiconductor chip was immersed in sodium borohydride 5 mM aqueous solution for 10 minutes and then rinsed in distilled water three times. Then, the substrate was immersed in a preparation of copper acetate 50 mM aqueous solution for 30 minutes and then rinsed in distilled water. After that, the substrate was immersed in electroless copper plating solution PS-503™ (available from Ebara-Udylite Co. Ltd.) for three hours to grow copper, thereby defining the package wirings of transverse wirings and vertical via wirings.

As a result, the PTFE porous sheet had got surface wirings of line width 25 μm, space 25 μm, and depth 20 μm. In addition, landless via wirings of diameter 55 μm were defined from side to side through the PTFE porous sheet. The junction of the surface wirings and the via wirings were contoured by smooth curves. In this junction, a length to width rate of the via wirings along the longer extension of the surface wirings to the shorter (L1/L2) was 1.5.

Impregnant resin for the porous sheet was a preparation of resin solution of 2 weight % aluminum chelate catalyst added to 100 weight % cyanate ester (available from Asahi-Ciba™ Corporation). The porous sheet provided with the conductors was impregnated with the resin solution and heated at 150 □ for five hours to cure. The impregnant resin was used not only for impregnation but to deposit solid substance into the solder-resist layer of 10 μm thickness over the porous sheet.

After hardened, the resin was eliminated from the tops of the pads of the package wirings by laser drill to clear the openings. The exposed pad surfaces were subjected to electroless nickel plating and succeedingly to immersion plating. The, solder balls were attached over the openings to form the solder bumps to finish the semiconductor package. It was observed that epoxy resin and benzocyclobutene could be substitutions for the impregnant resin of cyanate ester resin to manufacture the similar semiconductor package.

It was also found that, instead of repeating the exposure twice for the transverse wirings and the vertical via wirings, a half tone mask, capable of adjusting the transmitted light for the transverse wirings down to 10% of that for the via-hole wirings, could be used to fabricate the semiconductor package completely in the same procedures other than the exposure carried out under the condition of light exposure of 2000 mJ/cm² (wavelength 436 nm). Furthermore, in the same procedures other than the bonding of two of the semiconductor chips to the porous sheet, a semiconductor module could be fabricated which had two of the semiconductor chips and the package wirings mutually connecting them.

As a comparative examples, semiconductor packages were made by adjusting the transmitted light for the via-hole wirings relative to the junction with the transverse wirings in the junction, so that a length to width rate of the via wirings along the longer extension of the surface wirings to the shorter (L1/L2) were 1 and 1.2. In these semiconductor packages, tests on wiring resistance and heat cycle proved that when L1/L2=1, the wiring resistance became highest, which meant a poor device reliability, and that when L1/L2=1.5, the best performance was obtained.

The manufacturing method was modified to fabricate a semiconductor package, and in this case, after the via wirings and transverse wirings were formed in the package, it was bonded to the semiconductor chip. Specifically, the PTFE porous sheet, not being bonded to the semiconductor chip, was provided with the via wirings and the surface wirings in the similar manner, and after impregnated with the cyanate ester resin solution, it was pressed against and bonded to the semiconductor chip. The resultant semiconductor package was compared with the package fabricated by first bonding the porous sheet to the semiconductor chip and then plating the assembly. The latter semiconductor package showed a lower resistance between the terminal electrodes of the semiconductor chip and the via wirings. As a result of the heat cycle test, also, it was found that this package was more reliable in that the bonding at the interface between the electrodes and the via wirings was durable.

As has been described, in accordance with the embodiments of the present invention, provided is an electronic device module of a packaging structure suitable for thinning and downsizing the final product, and attaining enhanced electrical characteristics and reliability.

What is claimed is:

1. An electronic device module comprising:
a wiring substrate having an insulating substrate with a porous structure including continuous pores and wiring conductors selectively formed in the porous structure; and
an electronic device directly connected to said wiring conductors formed in the porous structure.

2. The electronic device module according to claim 1, wherein said wiring conductors in the wiring substrate are grouped into a first wiring conductor extending in parallel with a electronic device mounting surface of the porous insulating substrate and a second wiring conductor extending through the porous insulating substrate from its top surface to bottom surface.

3. The electronic device module according to claim 2, wherein said first wiring conductor is formed at a surface of said wiring substrate.

4. The electronic device module according to claim 2,
wherein said first wiring conductor is embedded in said wiring substrate.

5. The electronic device module according to claim 2, wherein, in the junction of the first and second wiring conductors defined as planes in parallel with the electronic device mounting surface of the wiring substrate, the second wiring conductor along the longer extension of the first wiring conductor is greater than that along the shorter extension of the first wiring conductor.

6. The electronic device module according to claim 1, wherein the wiring substrate and the electronic device are directly connected with each other by bonding layers provided at contacts of the wiring conductors with terminal electrodes of the electronic device.

7. The electronic device module according to claim 1, wherein a size of the electronic device and a size of the wiring substrate are substantially the same.

8. The electronic device module according to claim 1, wherein a size of the electronic device is smaller than the size of the wiring substrate.

9. The electronic device module according to claim 1, wherein the insulating substrate has almost the same coefficient of thermal expansion as that of the electronic device.

10. The electronic device module according to claim 1, wherein the electronic device is of semiconductor chip, and the wiring substrate serves as a package base on which the semiconductor chip is mounted.

11. The electronic device module according to claim 10, wherein the semiconductor chip that is mounted on a top surface of the package base, with its terminal electrodes facing downwards, and a part of the wiring conductors of the package base are directly coupled to the semiconductor chip, and other part of the wiring conductors extend to a bottom side of the package base.

12. The electronic device module according to claim 10, wherein the electronic device is of semiconductor chip that is mounted on a bottom surface of the package base, with its terminal electrodes facing upwards, and a part of the wiring conductors of the package base are directly coupled to the semiconductor chip, and other part of the wiring conductors extend at the bottom surface of the package base.

13. A manufacturing method of an electronic device module comprising:
mounting an electronic device on a surface of an insulating substrate having a porous structure including continuous pores and including photosensitive material which produces or vanishes ion exchange groups upon exposure to energy rays using a mask;
exposing the energy rays to change the photosensitive material; and
performing electroless plating to form wiring conductors in continuous pores generated by the change of the photosensitive material.

14. The method according to claim 13, further comprising impregnating plastic material into the porous insulating substrate.

15. The method according to claim 13, wherein said mask has a light shielding pattern which completely shields the ray, a partial transmitting pattern which partially transmits the ray and a through pattern which transmits the ray without attenuation.

16. The method according to claim 15, wherein said exposure is performed, if necessary, for the partial transmitting pattern, to converge the ray in the internal of the porous insulating substrate using a lens.
